(19) United States
(12) Patent Application Publication
(10) Pub. No.: US 2024/0363484 A1
(43) Pub. Date: Oct. 31, 2024

(54) THERMOELECTRIC COOLING FOR PACKAGE LEVEL THERMAL MANAGEMENT

(71) Applicant: Texas Instruments Incorporated, Dallas, TX (US)

(72) Inventors: Archana Venugopal, Santa Clara, CA (US); Jingjing Chen, Santa Clara, CA (US)

(21) Appl. No.: 18/308,411

(22) Filed: Apr. 27, 2023

(51) Int. Cl. H01L 23/38; H10N 10/01; H10N 10/17

(52) U.S. Cl. CPC H01L 23/38; H10N 10/01; H10N 10/17

(57) ABSTRACT

An electronic device includes a semiconductor die with first and second sides, a semiconductor layer extending to the first side, an array of unit cells arranged in rows columns, and a conductive reference terminal in the semiconductor layer that laterally surrounds the array, the first and second sides being spaced apart from one another by a thickness distance of 50 μm or less, and the respective unit cells including: a circuit component in the semiconductor layer; a holey semiconductor portion in the semiconductor layer that laterally surrounds the respective circuit component and includes holes that extend from the metallization structure toward the first side; and a conductive control terminal in the semiconductor layer that laterally surrounds the respective holey semiconductor portion, and an adhesive layer extends between the first side of the semiconductor die and a die attach pad.

### BACKGROUND

High power density electronic components can have local hot spots which degrade device performance and reliability. Air or liquid cooling solutions rely on heat removal through an external heat sink. However, such cooling solutions are designed to cool down the power device surface uniformly in steady state and overcooling exists in space and time while insufficient cooling occurs at the hotspots, resulting in poor overall cooling performance. The power rating of a component can degrade due to poor thermal conduction away from the die and/or poor lateral spreading of thermal hotspots on the die. Epoxy die attach adhesive acts as a thermal bottleneck at the interface of the die and lead frame and air gaps arising from surface irregularities at the interface additionally contribute to inefficient heat spreading.

### SUMMARY

In one aspect, an electronic device includes a semiconductor die with opposite first and second sides and an adhesive layer between the first side of the semiconductor die and a die attach pad. The semiconductor die has a semiconductor layer extending to the first side, a metallization structure extending from the semiconductor layer to the second side, an array of unit cells arranged in rows along a first direction and columns along an orthogonal second direction, and a conductive reference terminal in the semiconductor layer that laterally surrounds the array of unit cells. The first and second sides of the semiconductor die are spaced apart from one another by a thickness distance of 30 μm or more and 50 μm or less. The individual unit cells include a circuit component in the semiconductor layer, a holey semiconductor portion in the semiconductor layer that laterally surrounds the respective circuit component and includes holes that extend from the metallization structure toward the first side, as well as a conductive control terminal in the semiconductor layer that laterally surrounds the respective holey semiconductor portion.

In another aspect, a method of fabricating an electronic device includes: forming an array of unit cells in a semiconductor layer of a wafer, the unit cells arranged in rows along a first direction and columns along an orthogonal second direction, the respective unit cells including a circuit component in the semiconductor layer and a conductive control terminal laterally surrounding a lateral periphery of the respective unit cell in the semiconductor layer; forming a conductive reference terminal laterally surrounding the array of unit cells in the semiconductor layer; forming holes into a front side of the semiconductor layer in each unit cell along a third direction that is orthogonal to the first and second directions, the holes laterally surrounding the circuit component and laterally inward of the conductive reference terminal in each respective unit cell; back grinding an opposite back side of the semiconductor layer such that the holes are spaced apart from the back side of the semiconductor die along the third direction by a non-zero spacing distance; separating a semiconductor die with a portion of the semiconductor layer from the wafer; and engaging the back side of the semiconductor die to an adhesive layer to attach the semiconductor die to a die attach pad.

In a further aspect, an electronic device includes a semiconductor die, a conductive lead coupled to a circuit component of the semiconductor die, and a package structure that encloses a portion of the semiconductor die. The semiconductor die has opposite first and second sides, a semiconductor layer extending to the first side, a circuit component in the semiconductor layer, a metallization structure extending from the semiconductor layer to the second side, and a thermoelectric cooler, the thermoelectric cooler including a thermal channel configured to control a temperature of the circuit component, a conductive control terminal along the second side, and a conductive reference terminal that laterally surrounds the conductive control terminal along the second side.

In another aspect, a method of fabricating an electronic device includes: forming a thermoelectric cooler along a side of a wafer, the thermoelectric cooler including a thermal channel configured to control a temperature of a circuit component of the wafer, a conductive control terminal along the side, and a conductive reference terminal that laterally surrounds the conductive control terminal along the side; separating a semiconductor die with the thermoelectric cooler from the wafer; attaching the semiconductor die to a substrate or lead frame; and forming a package structure that encloses a portion of the semiconductor die.

### BRIEF DESCRIPTION OF THE DRAWINGS

FIG. 1 is a sectional side elevation view of an electronic device with an integrated thermoelectric cooler in a system taken along line 1-1 of FIG. 1A according to an embodiment.

FIG. 1A is a partial sectional top plan view of the electronic device taken along line 1A-1A of FIG. 1.

FIG. 1B is a partial sectional side elevation view of a portion of the electronic device taken along line 1B-1B of FIG. 1A.

FIG. 1C is a partial schematic view of example control circuit connections in the electronic device of FIGS. 1-1B.

FIG. 2 is a flow diagram of a method of fabricating an electronic device with an integrated thermoelectric cooler.

FIGS. 3-11 are partial sectional side elevation views of the electronic device of FIGS. 1-1C undergoing fabrication processing according to the method of FIG. 2.

FIG. 12 is a sectional side elevation view of an electronic device with an integrated thermoelectric cooler in a system taken along line 12-12 of FIG. 12A according to another embodiment.

FIG. 12A is a partial sectional top plan view of the electronic device taken along line 12A-12A of FIG. 12.

FIG. 12B is a partial schematic view of example control circuit connections in the electronic device of FIGS. 12 and 12A.

FIG. 13 is a sectional side elevation view of an electronic device with an integrated thermoelectric cooler in a system taken along line 13-13 of FIG. 13A according to another embodiment.

FIG. 13A is a partial sectional top plan view of the electronic device taken along line 13A-13A of FIG. 13.

FIG. 13B is a partial schematic view of example control circuit connections in the electronic device of FIGS. 13 and 13A.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value.

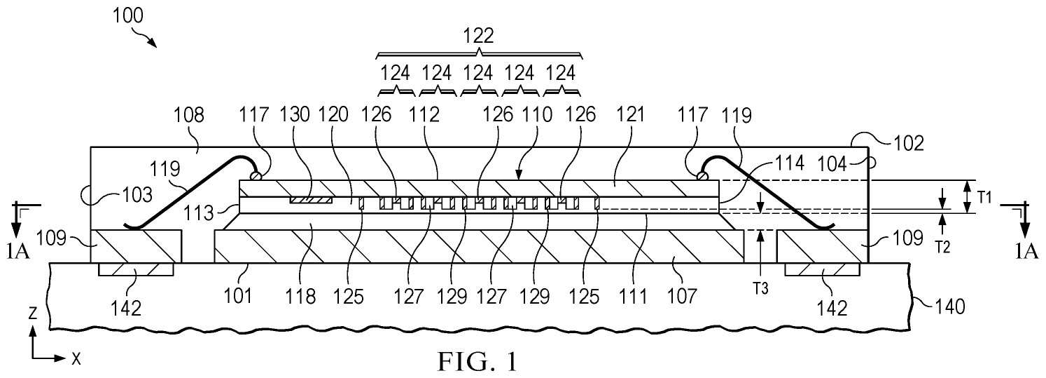

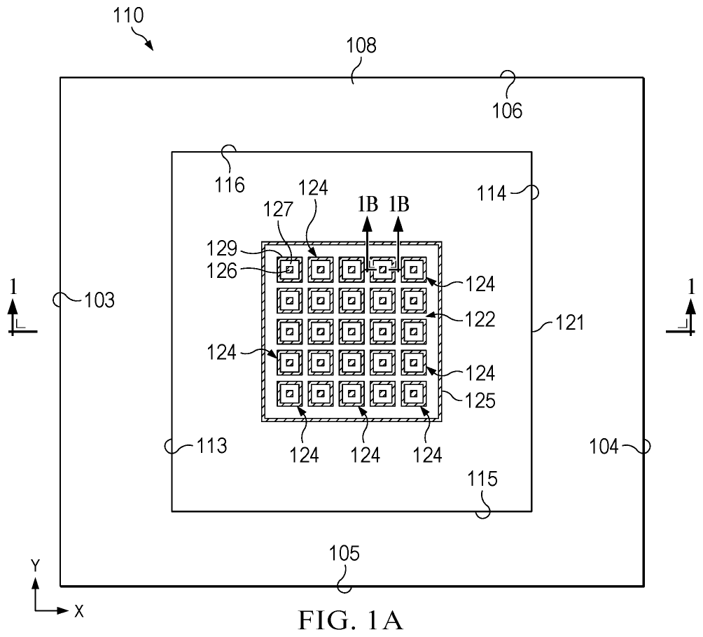

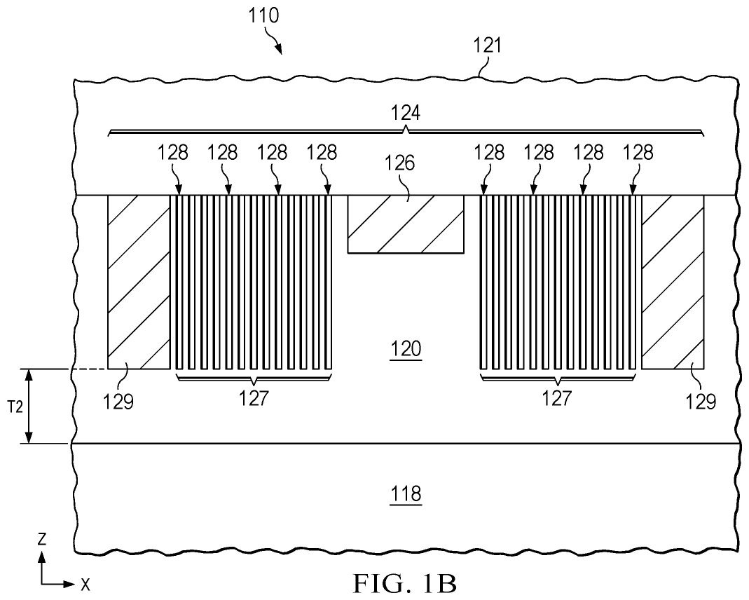

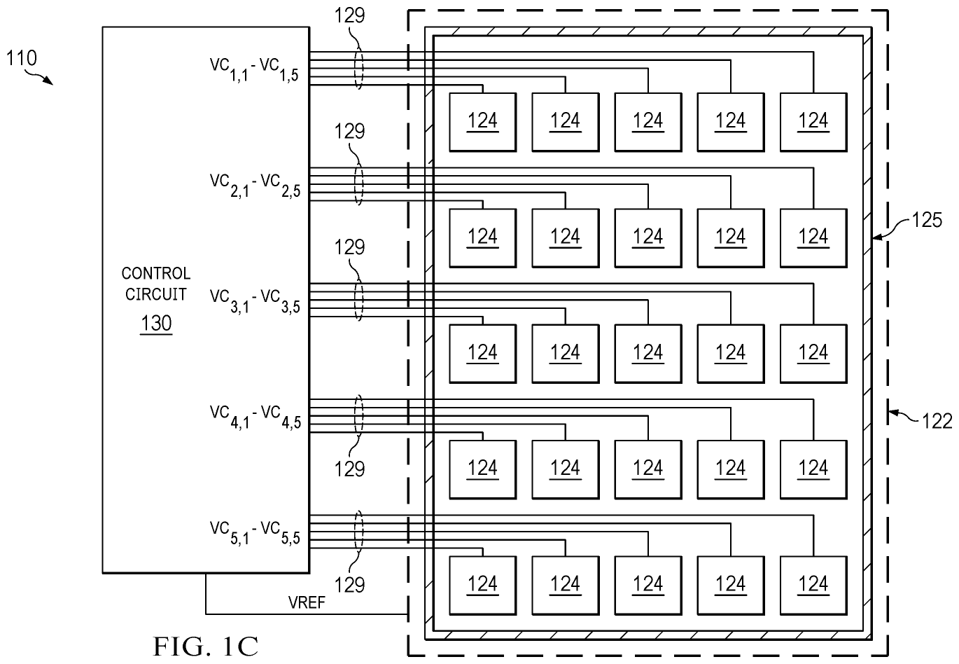

FIGS. 1-1C show a system with an electronic device 100 having an integrated thermoelectric cooler (TEC) operating according to a Peltier effect. FIG. 1 shows a side section view taken along line 1-1 of FIG. 1A, FIG. 1A shows a top view of the electronic device taken along line 1A-1A of FIG. 1, FIG. 1B shows a partial side view of a portion taken along line 1B-1B of FIG. 1A, and FIG. 1C shows a partial schematic view of example control circuit connections in the electronic device 100. FIG. 1 shows the electronic device 100 installed in an example system, such as a smart phone, laptop or desktop computer, a tablet, an automotive system, an industrial system, etc. The electronic device 100 is shown in an example position or orientation in a three-dimensional space with a first direction X, a perpendicular (orthogonal) second direction Y (FIG. 1A), and a third direction Z (FIGS. 1 and 1B) that is perpendicular (orthogonal) to the respective first and second directions X and Y. Structures or features along any two of these directions are orthogonal to one another.

The electronic device 100 has opposite first and second (e.g., bottom and top) sides 101 and 102, respectively, which are spaced apart from one another along the third direction Z (FIG. 1). The electronic device 100 also has laterally opposite third and fourth sides 103 and 104 (FIG. 1) that are spaced apart from one another along the first direction X, and opposite fifth and sixth sides spaced apart from one another along the second direction Y in the illustrated orientation. The device sides in one example have substantially planar outer surfaces. In other examples (not shown), one or more of the sides have curves, angled features, or other non-planar surface features. As best shown in FIG. 1, the electronic device 100 includes a die attach pad 107 (e.g., FIGS. 1 and 1B), such as an electrically conductive metal structure, a package structure 108, and conductive leads 109 partially exposed outside the package structure 108 to allow electrical connection to external structures or devices of a host system (e.g., by soldering, clamping in a socket, etc.).

The electronic device 100 includes a semiconductor die 110 having a first side 111 (e.g., bottom in FIG. 1) and an opposite second side 112 (e.g., top in FIG. 1), as well as respective laterally opposite third and fourth sides 113 and 114 (FIGS. 1 and 1A) spaced apart from one another along the first direction X and respective laterally opposite fifth and sixth sides 115 and 116 (FIG. 1A) that are spaced apart from one another along the second direction Y. The first and second sides 111 and 112 are spaced apart from one another by a thickness distance T1 (FIG. 1) along the third direction Z, and the thickness distance T1 is 30 μm or more and 50 μm or less. The semiconductor die 110 has one or more conductive terminals 117 (FIG. 1), such as conductive metal bond pads along the second side 112. The first side 111 of the semiconductor die 110 is attached to the die attach pad 107 by a die attach adhesive layer 118 (FIGS. 1 and 1B) that extends between the first side 111 of the semiconductor die 110 and the die attach pad 107. One or more of the conductive terminals 117 are electrically coupled by bond wires 119 to respective ones of the device leads 109 to provide system electrical connectivity to one or more circuits and/or components of the semiconductor die 110.

As best shown in FIG. 1, the semiconductor die 110 includes a semiconductor layer 120 that extends to the first side 111 of the semiconductor die 110, as well as a metallization structure 121 that extends from the semiconductor layer 120 to the second side 112 of the semiconductor die 110. The example semiconductor die 110 is or includes a semiconductor material such as silicon, gallium arsenide, etc. The semiconductor die 110 in one example includes one or more electronic components (e.g., transistors, diodes, resistors, etc.) formed on or in the semiconductor layer 120. The semiconductor die 110 can also include a single or multilevel metallization structure 121 along the second side 112 with conductive metal interconnections to the component or components of the semiconductor layer 120, where one or more further components (e.g., inductors, transformers, resistors, capacitors, etc.) can be formed in whole or in part in the metallization structure 121.

As shown in FIGS. 1 and 1A, the semiconductor die 110 includes an array 122 of unit cells 124 arranged in rows along the first direction X and columns along the second direction Y. FIG. 1B shows further details of one example unit cell 124 and the array 122 and associated electrical interconnections are also schematically illustrated in FIG. 1C. As shown in FIGS. 1, 1A, and 1C, the semiconductor die 110 also includes a conductive reference terminal 125 in the semiconductor layer 120 that laterally surrounds the array 122 of unit cells 124 (FIGS. 1A and 1C). The respective unit cells 124 include a circuit component 126 in the semiconductor layer 120. In one example, the circuit component 126 is a transistor, such as a laterally diffused (e.g., LDMOS) field effect transistor with drain, source and gate terminals (not shown). The respective unit cells 124 include a holey semiconductor portion 127 (FIGS. 1, 1A, and 1B) in the semiconductor layer 120 that laterally surrounds the respective circuit component 126.

As best shown in FIG. 1B, the holey semiconductor portion 127 includes holes 128 that extend from the metallization structure 121 downward along the third direction Z toward the first side 111 of the semiconductor die 110. As best shown in FIG. 1B, the bottoms of the holes 128 are spaced apart from the first side 111 of the semiconductor die 110 along the third direction Z by a non-zero spacing distance T2. In one example, the non-zero spacing distance T2 is less than a thickness T3 of the adhesive layer 118 along the third direction Z (FIG. 1). In addition, the individual unit cells 124 include a conductive control terminal 129 in the semiconductor layer 120 that laterally surrounds the respective holey semiconductor portion 127. In one example, the conductive reference terminal 125 and the conductive control terminals 129 extend to approximately the same depth as the holes 128, although not a requirement of all possible implementations. The conductive reference terminal 125 and the conductive control terminals 129 in one example include conductive (e.g., doped) polysilicon or metal or other conductive metal. In one example, the holes 128 are formed by deep trench etching, through silicon via type processing or another suitable process, and may replace the poly fill used in deep trench isolation structures with a different material having better thermoelectric properties (or no fill material). In certain implementations, the dimensions and/or the placement/location of the TEC structure can be tailored to provide a desired effect on the cooling and thermal performance of the electronic device 100.

In one example, the holey semiconductor portion 127 and the conductive control terminal 129 form a thermoelectric cooler TEC of the respective unit cells 124. As best shown in FIGS. 1 and 1C, the semiconductor die 110 includes a control circuit 130. The control circuit 130 is configured to provide a control voltage signal VC to the conductive control terminal 129 of the respective unit cells 124 to control the temperature of the circuit component 126 of the respective one of unit cells 124 at a voltage relative to a voltage VREF (FIG. 1C) of the conductive reference terminal 125 to control heating or cooling of the thermoelectric cooler TEC of the respective unit cells 124. In one example, the control circuit 130 provides individual control voltage signals VC to selectively provide local heating and/or cooling (or no voltage signal for no thermal effect) for the individual unit cells 124 to address one or more thermal hot spots and/or transient thermal events within the array 122, and the thermal control can be based on predetermined thermal patterns and/or on thermal feedback signals, such as temperature sensing circuitry within the semiconductor die 110 and/or within the packaged electronic device 100. Illustrated example help reduce peak temperature rise during transient events in power devices using the concept of holey silicon and thermoelectric cooling. The electronic device 100 advantageously utilizes the thermal impedance from a package structure components, such as the die attach adhesive layer 118 and/or other package structures of the device bill of material (BOM) to facilitate transient temperature reduction. In one example, the adhesive layer 118 provides a thermal load to the thermoelectric cooler TEC of the respective unit cells 124 and the reduced die thickness distance T1 facilitates thermal management by the control circuit 130 by providing the thermal loading (e.g., relatively high thermal resistance) of the adhesive layer 118 in proximity to the vertical thermal channel of the holey semiconductor portion 127.

The electronic device 100 is shown installed in a system in FIG. 1, such as a smart phone, laptop or desktop computer, a tablet, an automotive system, an industrial system, etc. In the illustrated example, the system includes a printed circuit board (PCB) 140 with other system circuits and components (not shown). The electronic device 100 is attached to the circuit board 140 with one or more of the conductive leads 109 electrically coupled to respective ones of the conductive terminals 117 of the semiconductor die 110 and to a respective conductive feature 142 of the circuit board 140. The electronic device 100 in one example provides integrated device-scale holey silicon-based thermoelectric cooling to facilitate efficient hotspot cooling to accommodate transient heating conditions for power transistors or other circuit components. Instead of cooling the entire semiconductor die, the integrated thermoelectric cooling system cools down a specific hotspot area, which provides high-precision temperature control in transistor arrays. Certain implementations provide transient current pulses for the control voltage signals VC to perform more significant cooling under transient heating conditions, and the transient TEC pulse shape and current level can be tailored for a given design to enhance the cooling effect.

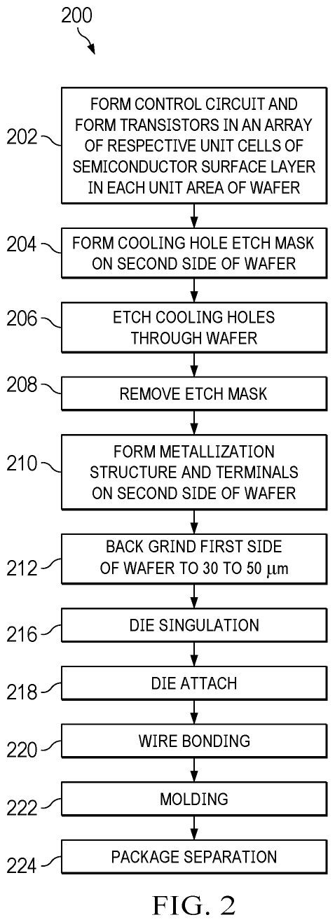

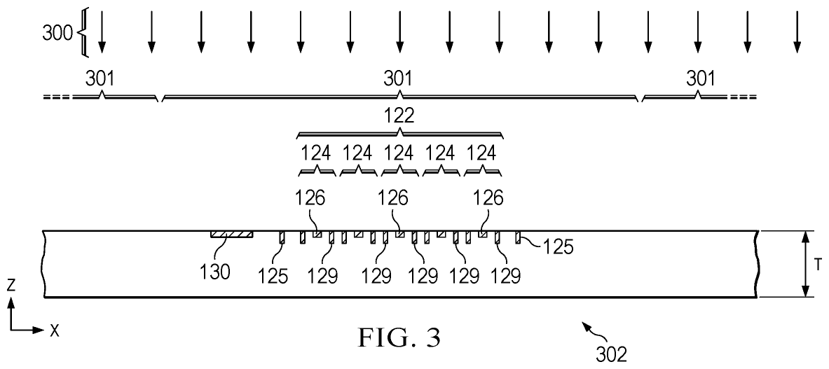

Referring now to FIGS. 2-11, FIG. 2 illustrates a method 200 of fabricating an electronic device with integrated thermoelectric cooling and FIGS. 3-11 show the electronic device 100 undergoing fabrication processing according to an example implementation of the method 200. The method 200 includes wafer level processing at 202 to form circuit components and structures in the semiconductor layer of a starting wafer. FIG. 3 shows one example, in which wafer processing operations 300 are performed that form the control circuit 130, the conductive reference terminal 125, the circuit components 126 and the conductive control terminals 129 in each unit area 301 of a starting wafer 302. The starting wafer in one example is a silicon wafer with a starting thickness T. In other examples, a different semiconductor wafer can be used, such as a silicon over insulator (SOI) wafer or a wafer having a different type of semiconductor material (e.g., gallium arsenide, etc.). The processing at 202 forms the array 122 of unit cells 124 in each unit area 301 of the semiconductor layer 120 of the wafer 302 arranged in rows and columns that individually include the circuit component 126 and the conductive control terminal 129 laterally surrounding the lateral periphery of the respective unit cells 124 in the semiconductor layer 120, and the processing at 202 forms the conductive reference terminal 125 laterally surrounding the array 122 of unit cells 124 in the semiconductor layer 120 in each unit area 301.

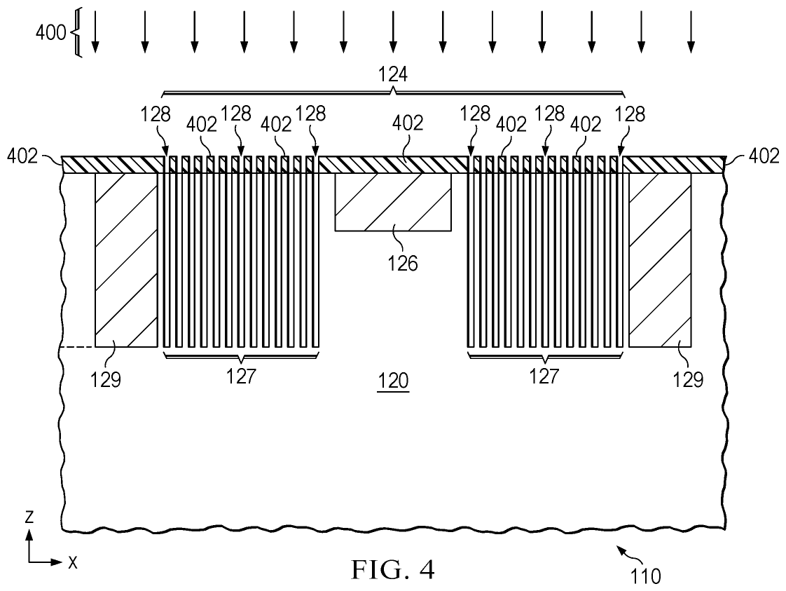

The cooling holes are formed at 204-208 in FIG. 2, including forming a patterned cooling hole etch mask at 204. FIG. 4 shows one example, in which a hole formation process 400 is performed (e.g., blanket deposition of mask material, patterned exposure and material removal) that forms a patterned etch mask 402 with openings that expose prospective portions of the semiconductor layer 120 into which the holes are to be formed. The holes are etched at 206 in FIG. 2. The process 400 in FIG. 4 includes an etch process that forms the TEC cooling holes 128 downward into the semiconductor layer 120 along the third direction Z, after which the etch mask 402 is removed at 208 in FIG. 2. The hole formation at 206 forms the holes 128 into the front side of the semiconductor layer 120 in each unit cell 124 along the third direction Z with the holes 128 laterally surrounding the circuit component 126 and laterally inward of the conductive reference terminal 125 in each respective unit cell 124.

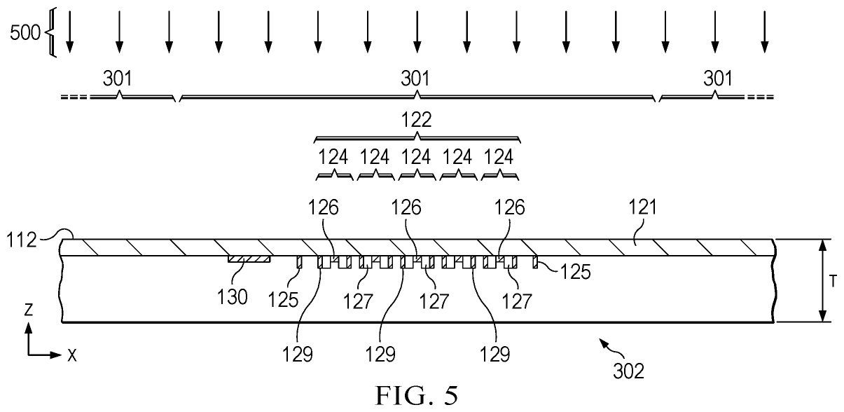

A metallization structure is formed at 210 in FIG. 2. FIG. 5 shows one example, in which a metallization process 500 is performed that forms a single or multilevel metallization structure 121 on the semiconductor layer of the wafer 302. The metallization structure 121 in one example forms the second or top side of the wafer and subsequently separated semiconductor dies 110, and the metallization structure 121 covers the cooling holes 128.

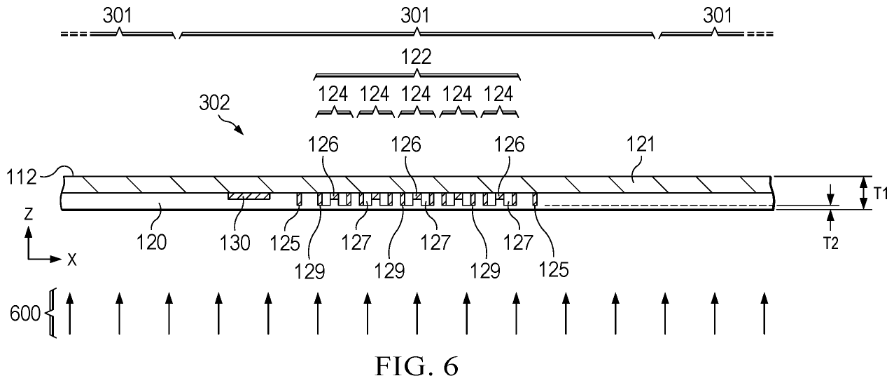

At 212 in FIG. 2, the back or first side of the starting wafer is ground to set the final wafer/die thickness. FIG. 6 shows one example, in which a wafer grinding process 600 is performed that back grinds the wafer 302 to set the final thickness distance T1 of the wafer 302 and of the semiconductor dies subsequently separated therefrom (e.g., 30 μm or more and 50 μm or less). In addition, the back grinding process 600 sets the non-zero spacing distance T2 between the bottoms of the holes 128 and the first side 111 of the wafer and subsequently separated semiconductor die 110 along the third direction Z.

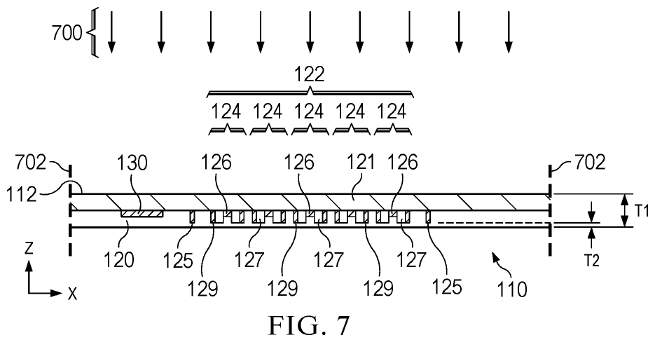

At 216 in FIG. 2, the method 200 continues with die singulation or separation processing. FIG. 7 shows one example, in which a cutting process 700 is performed that cuts along scribe streets or scribe areas shown as lines 702 in FIG. 7 between adjacent unit areas of the processed wafer in order to separate individual semiconductor dies 110 from the wafer structure. Any suitable separation or cutting process 700 can be used at 216, such as saw cutting, laser cutting, etching, or combinations thereof, etc.

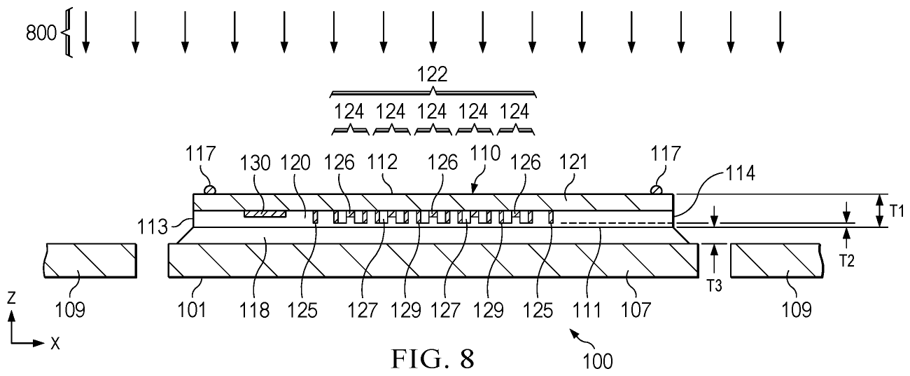

The method 200 continues with die attachment at 218 in FIG. 2. FIG. 8 shows one example, in which a lead frame panel array is provided having rows and columns of unit areas, and individual ones of the separated semiconductor dies 110 are attached to die attach pads 107 or other suitable support structures of the lead frame panel array for subsequent electrical interconnection. A die attach process 800 is performed that includes dispensing or otherwise forming the adhesive layer 118 on select portions (e.g., die attach pads 107) of the lead frame panel array and engaging the back side 111 of the semiconductor die 110 to the adhesive layer 118 to attach the semiconductor die 110 to a die attach pad 107 in each unit area of the lead frame panel array.

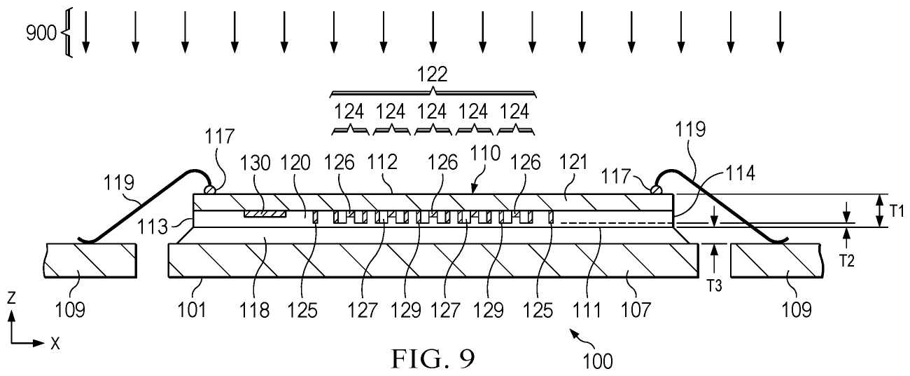

The method 200 in one example includes wire bonding at 220 in FIG. 2. FIG. 9 shows one example, in which a wire bonding process 900 is performed that forms the bond wires 119 to electrically couple the conductive terminals 117 of the semiconductor die 110 to respective ones of the device leads 109 to provide system electrical connectivity to one or more circuits and/or components of the semiconductor die 110.

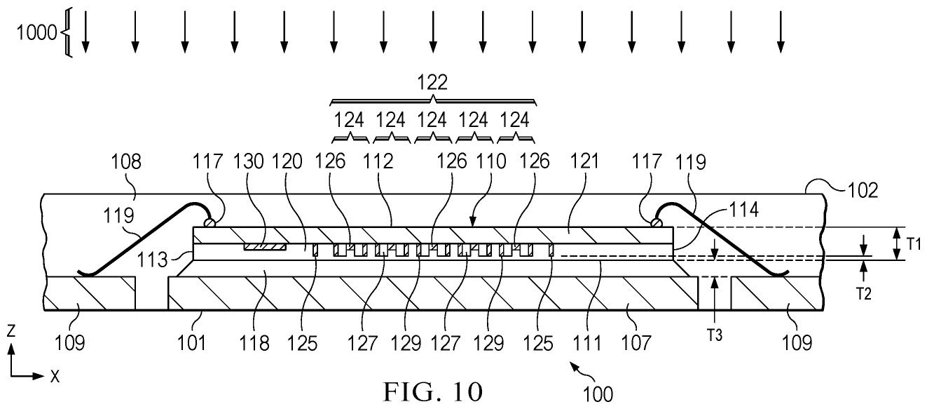

The method 200 continues at 222 in FIG. 2 with package structure formation. In one example, the processing at 222 includes molding operations to form the molded package structure 108 in individual unit areas or groups thereof in the panel array structure. FIG. 10 shows one example, in which a molding process 1000 is performed that forms the package structure 108. In one implementation, the molding at 222 can be performed using any suitable molding equipment. In one implementation, a single mold cavity can be used for an entire panel array or multiple cavities can be used for individual unit areas thereof or groups of unit areas, such as column-wise mold cavities, or combinations thereof. The package structure 108 in one example at least partially encloses the semiconductor die 110 and upper portions of the die attach pad 107 and the leads 109 in each unit area of the panel array. In certain examples, the molding processing at 222 in FIG. 2 can include separate formation of multiple molded portions of a package structure, such as initial mold underfill formation, followed by a subsequent top molding process, or the molding at 222 creates a mold underfill followed by attachment of a metal lid (not shown) over at least a portion of a top side of the semiconductor die 110 without forming a second top mold structure. The molding processing at 222 in one example exposes a lower side of the die attach pad 107 and the leads 109. In another example implementation, the molding process covers the bottom side of the die attach pad 107.

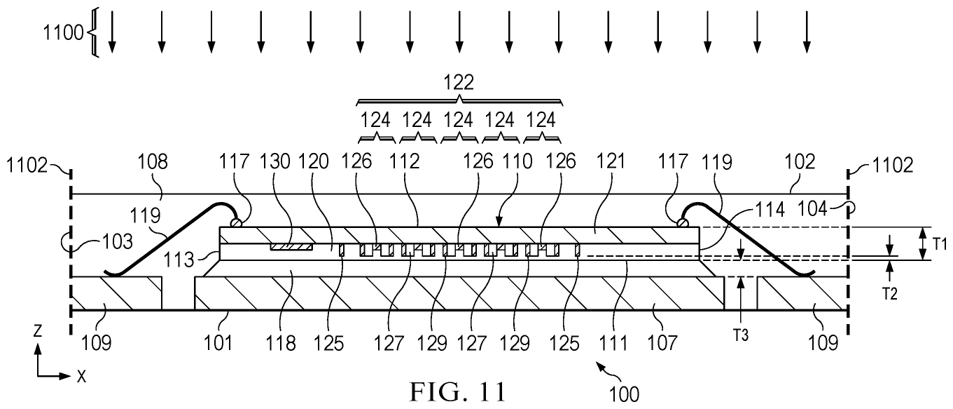

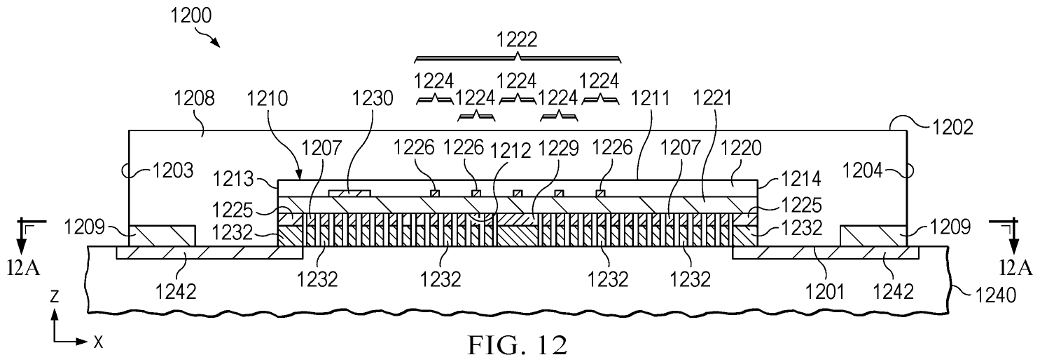

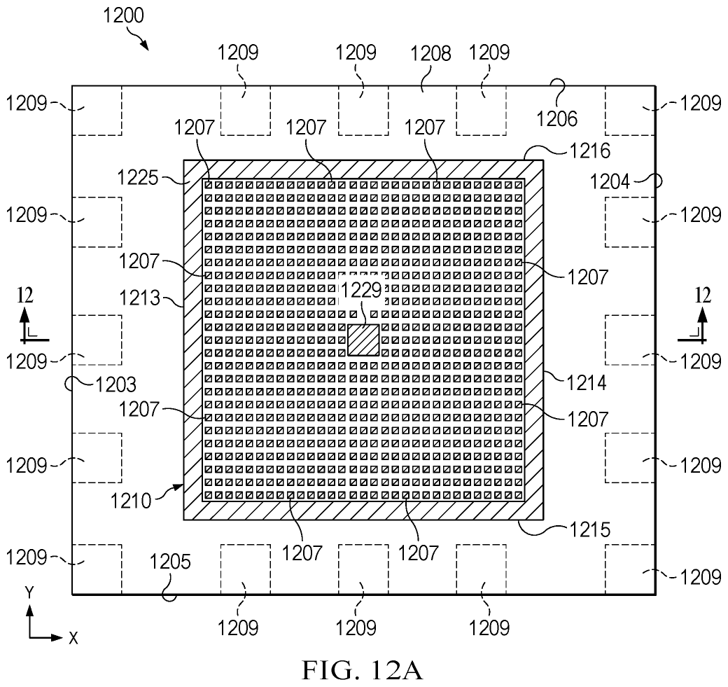

The method 200 in one example also includes package separation at 224 in FIG. 2 to separate individual packaged electronic devices 100 from the processed panel array structure, for example, to form quad flat no lead (e.g., QFN) or other device types and shapes. FIG. 11 shows one example, in which a saw cutting separation process 1100 is performed that separates individual packaged electronic devices 100 from the processed panel array structure by cutting along lines 1102. Any suitable cutting or separation process can be used, including without limitation saw cutting, laser cutting, chemical etching, etc. or combinations thereof. In certain examples, the method 200 can also include final device testing after package separation at 224 and/or wafer level testing (e.g., before die separation at 228 in FIG. 2).

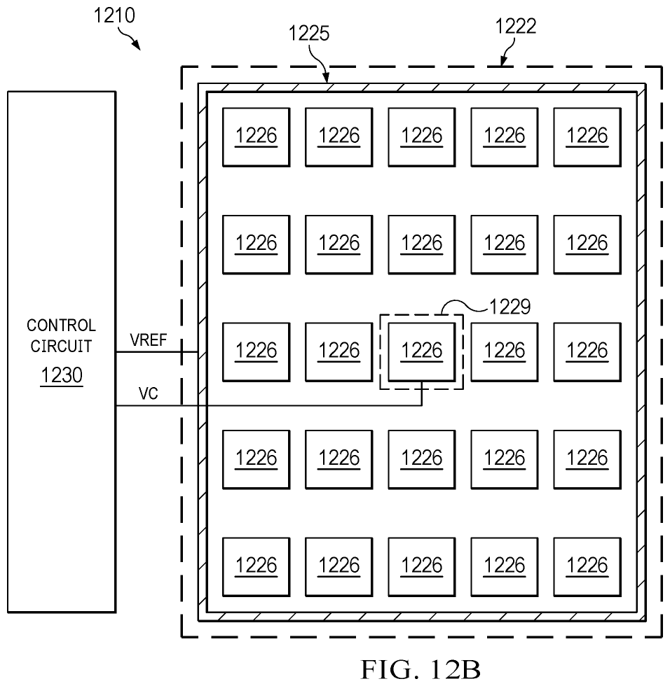

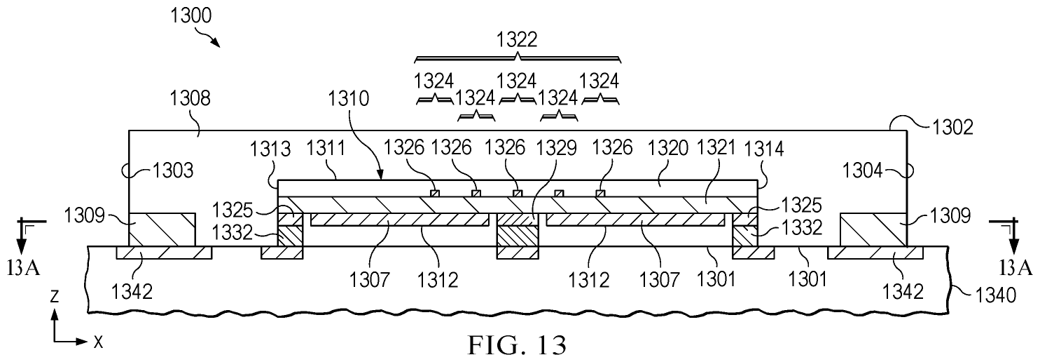

FIGS. 12-12B show another electronic device 1200 with an integrated thermoelectric cooler in a system, in which FIG. 12 shows a side section view of the electronic device 1200 taken along line 12-12 of FIG. 12A, FIG. 12A shows a top view of the electronic device 1200 taken along line 12A-12A of FIG. 12 and FIG. 12B shows example control circuit connections in the electronic device 1200. The electronic device 1200 in this example has integrated thermoelectric cooling features using a thermoelectric cooler (TEC) operating according to a Peltier effect with packaging structures and/or host circuit board features, for example, with flip-chip semiconductor die conductive metal bumps and/or circuit board traces operating as a Peltier cooler control terminal or electrode and a die conductive metal bump and/or circuit board trace operating as a ground or other reference electrode of the thermoelectric cooler. FIG. 12 shows the electronic device 1200 installed in an example system, such as a smart phone, laptop or desktop computer, a tablet, an automotive system, an industrial system, etc. The electronic device 1200 is shown in an example position or orientation in a three-dimensional space with a first direction X, a perpendicular (orthogonal) second direction Y (FIG. 12A), and an orthogonal third direction Z (FIG. 12), where structures or features along any two of these directions are orthogonal to one another. The electronic device 1200 has opposite first and second (e.g., bottom and top) sides 1201 and 1202 (FIG. 12), respectively, which are spaced apart from one another along the third direction Z, as well as laterally opposite third and fourth sides 1203 and 1204 (FIGS. 12 and 12A) that are spaced apart from one another along the first direction X, and opposite fifth and sixth sides 1205 and 1206, respectively, which are spaced apart from one another along the second direction Y in the illustrated orientation. The device sides 1201-1206 in one example have substantially planar outer surfaces. In other examples (not shown), one or more of the sides 1201-1206 have curves, angled features, or other non-planar surface features.

As best shown in FIG. 12, the electronic device 1200 includes a substrate with conductive metal features (e.g., FIGS. 12 and 12A) as well as a package structure 1208 (e.g., epoxy molding compound, etc.), and conductive leads 1209 partially exposed outside the package structure 1208 to allow electrical connection to external structures or devices of a host system (e.g., by soldering, clamping in a socket, etc.). The electronic device 1200 has a semiconductor die 1210 with conductive metal or solder bumps 1207 (FIGS. 12 and 12A) arranged in an array to provide a holey structure for thermoelectric cooling via a Peltier effect. The semiconductor die 1210 has a first side 1211 (e.g., top in FIG. 12) and an opposite second side 1212 (e.g., bottom in FIG. 12), as well as respective laterally opposite third and fourth sides 1213 and 1214 (FIGS. 12 and 12A) spaced apart from one another along the first direction X and respective laterally opposite fifth and sixth sides 1215 and 1216 (FIG. 12A) that are spaced apart from one another along the second direction Y. The semiconductor die 1210 has one or more conductive metal bumps 1207, 1225 and 1229 (e.g., copper pillars, solder bumps, etc.) along the second side 1212, some or all of which are flip chip attached (e.g., soldered) to respective conductive features 1232 of the substrate of the electronic device 1200.

As best shown in FIG. 12, the semiconductor die 1210 has a semiconductor layer 1220 extending to the first side 1211, circuit components 1226, such as transistors in the semiconductor layer 1220, and a metallization structure 1221 extending from the semiconductor layer 1220 to the second side 1212. The semiconductor die 1210 has a thermoelectric cooler that includes a thermal channel formed by spaces between the array of conductive bumps 1207. The thermal channel is configured to control the temperature of the circuit components 1226. The conductive die bumps also include a conductive control terminal 1229 along the second side 1212, and a conductive reference terminal 1225 that laterally surrounds the conductive control terminal 1229 along the second side 1212 of the semiconductor die 1210. The conductive leads 1209 in one example are coupled to the circuit components 1226 of the semiconductor die 1210, and the package structure 1208 encloses a portion of the semiconductor die 1210. The example semiconductor die 1210 is or includes a semiconductor material such as silicon, gallium arsenide, etc. The semiconductor die 1210 in one example includes one or more electronic components (e.g., transistors, diodes, resistors, etc.) formed on or in the semiconductor layer 1220. The semiconductor die 1210 can also include a single or multilevel metallization structure 1221 along the second side 1212 with conductive metal interconnections to the component or components of the semiconductor layer 1220, where one or more further components (e.g., inductors, transformers, resistors, capacitors, etc.) can be formed in whole or in part in the metallization structure 1221.

As shown in FIG. 12, the semiconductor die 1210 includes an array 1222 of unit cells 1224 having a respective one of the circuit components 1226 arranged in rows along the first direction X and columns along the second direction Y. FIG. 12B schematically shows the array 1222 and associated electrical interconnections of the thermoelectric heater terminals. The semiconductor die 1210 also includes a conductive reference terminal 1225 formed as a conductive metal or solder structure along the second side 1212 that laterally surrounds the array 1222 of unit cells 1224. The respective unit cells 1224 include a circuit component 1226 in the semiconductor layer 1220. In one example, the circuit component 1226 is a transistor, such as a laterally diffused (e.g., LDMOS) field effect transistor with drain, source and gate terminals (not shown).

The TEC of the electronic device 1200 includes a conductive reference terminal 1225 formed as a first conductive bump along the second side 1212 of the semiconductor die 1210, and the conductive control terminal 1229 is a second conductive bump along the second side 1212. As shown in FIGS. 12 and 12A, the TEC thermal channel includes an array of further conductive bumps 1207 spaced apart from one another along the second side 1212 and arranged in rows along the first direction X and columns along the second direction Y. The array of further conductive bumps 1207 laterally surrounds the conductive control terminal 1229 along the second side 1212, and the conductive reference terminal 1225 laterally surrounds the array of further conductive bumps 1207 along the second side 1212. In the illustrated example, the connection of individual further bumps 1207 to respective conductive substrate features 1232 extends the thermal channel of the thermoelectric cooler structure in the packaged electronic device.

Moreover, the connection of one or both of the conductive reference terminal bump 1225 and/or the conductive control terminal bump 1229 to respective conductive substrate features 1232 extends the thermal channel of the thermoelectric cooler structure in the packaged electronic device and allows control and/or reference voltage signals VC. VREF to be generated by control circuitry of either or both of the electronic device 1200 and/or a host circuit board.

The electronic device 1200 is shown installed in a system in FIG. 12, such as a smart phone, laptop or desktop computer, a tablet, an automotive system, an industrial system, etc. In the illustrated example, the system includes a printed circuit board (PCB) 1240 with other system circuits and components (not shown). The electronic device 1200 is attached to the circuit board 1240 with one or more of the conductive leads 1209 electrically coupled to respective ones of the conductive terminals 1217 of the semiconductor die 1210 and to a respective conductive feature 1242 of the circuit board 1240. The electronic device 1200 in one example provides integrated device-scale holey bump array thermoelectric cooling to facilitate efficient hotspot cooling to accommodate transient heating conditions for power transistors or other circuit components 1236. Certain implementations provide transient current pulses for the control voltage signals VC to perform more significant cooling under transient heating conditions.

As best shown in FIGS. 12 and 12B, the semiconductor die 1210 includes a control circuit 1230 in one example. In another example, the control circuit 1230 can be formed in circuitry of a host circuit board to which the electronic device 1200 is connected. The control circuit 1230 is configured to provide a control voltage signal VC to the conductive control terminal 1229 to control the temperature of the circuit components 1226 at a voltage relative to a voltage VREF (FIG. 12B) of the conductive reference terminal 1225. The reference voltage VREF can be supplied by either the electronic device 1200 or a host circuit board.

The electronic device 1200 can be formed by suitable fabrication processing steps including forming a thermoelectric cooler TEC along a side 1212 of a wafer, the thermoelectric cooler including a thermal channel 1207 configured to control a temperature of a circuit component 1226 of the wafer, a conductive control terminal 1229 along the side 1212, and a conductive reference terminal 1225 that laterally surrounds the conductive control terminal 1229 along the side 1212 of the wafer, as well as separating a semiconductor die 1210 with the thermoelectric cooler TEC from the wafer, attaching the semiconductor die 1210 to a substrate or lead frame, and forming a package structure 1208 that encloses a portion of the semiconductor die 1210. In one implementation, forming the thermoelectric cooler TEC includes forming the conductive reference terminal 1225 as a first conductive bump along the side 1212 and forming the conductive control terminal 1229 as a second conductive bump along the side 1212. In these or another example, forming the thermoelectric cooler TEC includes forming the thermal channel 1207 as an array of conductive bumps 1207 spaced apart from one another along the side 1212 and arranged in rows along a first direction X and columns along an orthogonal second direction Y, where the array of conductive bumps 1207 laterally surrounds the conductive control terminal 1229 along the side 1212 and the conductive reference terminal 1225 laterally surrounds the array of conductive bumps 1207 along the side 1212.

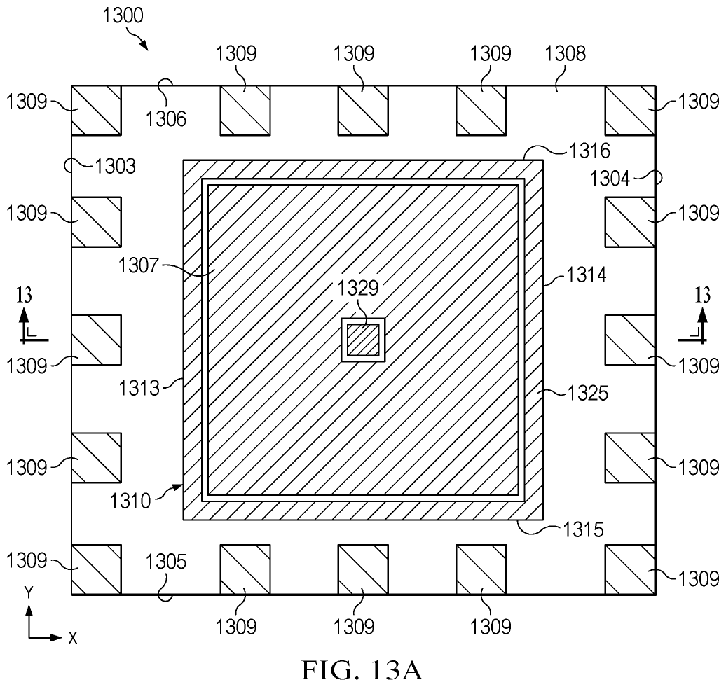

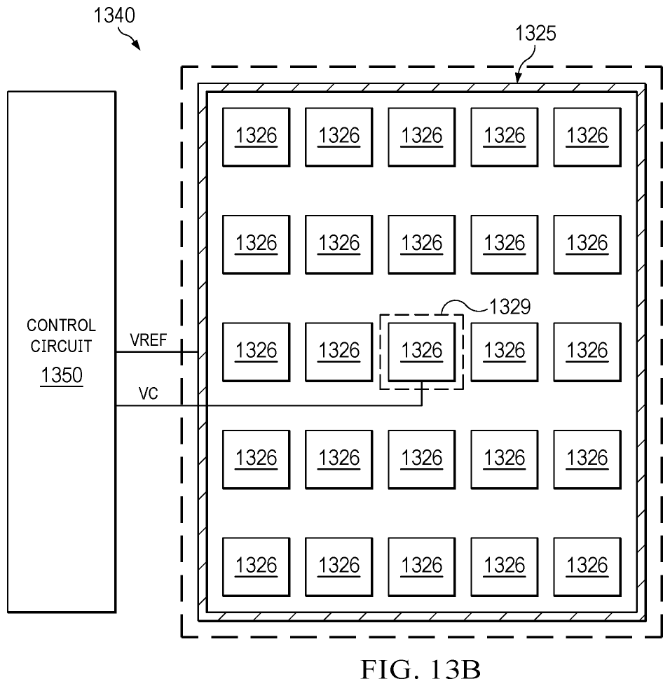

FIGS. 13-13B show yet another example electronic device 1300 with an integrated thermoelectric cooler in a system. FIG. 13 shows a side section view of the electronic device 1300 taken along line 13-13 of FIG. 13A, FIG. 13A shows a top view of the electronic device 1300 taken along line 13A-13A of FIG. 13 and FIG. 13B shows example control circuit connections in the electronic device 1300. The electronic device 1300 in this example has integrated thermoelectric cooling features using a thermoelectric cooler (TEC) operating according to a Peltier effect with packaging structures and/or host circuit board features, for example, with flip-chip semiconductor die conductive metal bumps and/or circuit board traces operating as a Peltier cooler control terminal or electrode and a die conductive metal bump and/or circuit board trace operating as a ground or other reference electrode of the thermoelectric cooler.

FIG. 13 shows the electronic device 1300 installed in an example system, such as a smart phone, laptop or desktop computer, a tablet, an automotive system, an industrial system, etc. The electronic device 1300 is shown in an example position or orientation in a three-dimensional space with a first direction X, a perpendicular (orthogonal) second direction Y (FIG. 13A), and an orthogonal third direction Z (FIG. 13), where structures or features along any two of these directions are orthogonal to one another. The electronic device 1300 has opposite first and second (e.g., bottom and top) sides 1301 and 1302 (FIG. 13), respectively, which are spaced apart from one another along the third direction Z, as well as laterally opposite third and fourth sides 1303 and 1304 (FIGS. 13 and 13A) that are spaced apart from one another along the first direction X, and opposite fifth and sixth sides 1305 and 1306, respectively, which are spaced apart from one another along the second direction Y in the illustrated orientation. The device sides 1301-1306 in one example have substantially planar outer surfaces. In other examples (not shown), one or more of the sides 1301-1306 have curves, angled features, or other non-planar surface features.

As best shown in FIG. 13, the electronic device 1300 includes a substrate with conductive metal features (e.g., FIGS. 13 and 13A) as well as a package structure 1308 (e.g., epoxy molding compound, etc.), and conductive leads 1309 partially exposed outside the package structure 1308 to allow electrical connection to external structures or devices of a host system (e.g., by soldering, clamping in a socket, etc.). The electronic device 1300 has a semiconductor die 1310 with a conductive lattice structure 1307 along the second side 1312 to provide a holey structure for thermoelectric cooling via a Peltier effect. The conductive lattice structure 1307 laterally surrounds a conductive control terminal 1329 (e.g., a conductive metal or solder bump) along the second side 1312, and a conductive reference terminal 1325 laterally surrounds the conductive lattice structure 1307 along the second side 1312 of the semiconductor die 1310. The semiconductor die 110 has a first side 1311 (e.g., top in FIG. 13) and an opposite second side 1312 (e.g., bottom in FIG. 13), as well as respective laterally opposite third and fourth sides 1313 and 1314 (FIGS. 13 and 13A) spaced apart from one another along the first direction X and respective laterally opposite fifth and sixth sides 1315 and 1316 (FIG. 13A) that are spaced apart from one another along the second direction Y. The semiconductor die 1310 has one or more conductive metal bumps 1325 and 1329 (e.g., copper pillars, solder bumps, etc.) along the second side 1312, some or all of which are flip chip attached (e.g., soldered) to respective conductive features 1332 of the substrate of the electronic device 1300.

As best shown in FIG. 13, the semiconductor die 1310 has a semiconductor layer 1320 extending to the first side 1311, circuit components 1326, such as transistors in the semiconductor layer 1320, and a metallization structure 1321 extending from the semiconductor layer 1320 to the second side 1312. The semiconductor die 1310 has a thermoelectric cooler that includes a thermal channel formed by spaces between the conductive lattice bump structure 1307. The thermal channel is configured to control the temperature of the circuit components 1326. The conductive die bumps also include a conductive control terminal 1329 along the second side 1312, and a conductive reference terminal 1325 that laterally surrounds the conductive control terminal 1329 along the second side 1312 of the semiconductor die 1310. The conductive leads 1309 in one example are coupled to the circuit components 1326 of the semiconductor die 1310, and the package structure 1308 encloses a portion of the semiconductor die 1310. The example semiconductor die 1310 is or includes a semiconductor material such as silicon, gallium arsenide, etc. The semiconductor die 1310 in one example includes one or more electronic components (e.g., transistors, diodes, resistors, etc.) formed on or in the semiconductor layer 1320. The semiconductor die 1310 can also include a single or multilevel metallization structure 1321 along the second side 1312 with conductive metal interconnections to the component or components of the semiconductor layer 1320, where one or more further components (e.g., inductors, transformers, resistors, capacitors, etc.) can be formed in whole or in part in the metallization structure 1321.

As shown in FIG. 13, the semiconductor die 1310 includes an array 1322 of unit cells 1324 having a respective one of the circuit components 1326 arranged in rows along the first direction X and columns along the second direction Y. FIG. 13B schematically shows the array 1322 and associated electrical interconnections of the thermoelectric heater terminals. The semiconductor die 1310 also includes the conductive reference terminal 1325 formed as a conductive metal or solder structure along the second side 1312 that laterally surrounds the array 1322 of unit cells 1324. The respective unit cells 1324 include a circuit component 1326 in the semiconductor layer 1320. In one example, the circuit component 1326 is a transistor, such as a laterally diffused (e.g., LDMOS) field effect transistor with drain, source and gate terminals (not shown).

The TEC of the electronic device 1300 includes a conductive reference terminal 1325 formed as a first conductive bump along the second side 1312 of the semiconductor die 1310, and the conductive control terminal 1329 is a second conductive bump along the second side 1312. As shown in FIGS. 13 and 13A, the TEC thermal channel includes the conductive lattice bump structure 1307 along the second side 1312. The conductive lattice bump structure 1307 laterally surrounds the conductive control terminal 1329 along the second side 1312, and the conductive reference terminal 1325 laterally surrounds the conductive lattice bump structure 1307 along the second side 1312. In the illustrated example, the connection of one or both of the conductive reference terminal bump 1325 and/or the conductive control terminal bump 1329 to respective conductive substrate features 1332 extends the thermal channel of the thermoelectric cooler structure in the packaged electronic device and allows control and/or reference voltage signals VC. VREF to be generated by control circuitry of either or both of the electronic device 1300 and/or a host circuit board.

The electronic device 1300 is shown installed in a system in FIG. 13, such as a smart phone, laptop or desktop computer, a tablet, an automotive system, an industrial system, etc. In the illustrated example, the system includes a printed circuit board (PCB) 1340 with other system circuits and components (not shown). The electronic device 1300 is attached to the circuit board 1340 with one or more of the conductive leads 1309 electrically coupled to respective ones of the conductive terminals 1317 of the semiconductor die 1310 and to a respective conductive feature 1342 of the circuit board 1340. The electronic device 1300 in one example provides integrated device-scale holey bump array thermoelectric cooling to facilitate efficient hotspot cooling to accommodate transient heating conditions for power transistors or other circuit components 1326. Certain implementations provide transient current pulses for the control voltage signals VC to perform more significant cooling under transient heating conditions.

As best shown in FIG. 13B, the host circuit board 1340 can include a control circuit 1350 in one example. In another example, the control circuit 1350 can be formed in circuitry of the semiconductor die 1310. The control circuit 1350 is configured to provide a control voltage signal VC to the conductive control terminal 1329 to control the temperature of the circuit components 1326 at a voltage relative to a voltage VREF (FIG. 13B) of the conductive reference terminal 1325. The reference voltage VREF can be supplied by either the electronic device 1300 or the host circuit board 1340.

The electronic device 1300 can be formed by suitable fabrication processing steps including forming a thermoelectric cooler TEC along a side 1312 of a wafer, the thermoelectric cooler including a thermal channel 1307 configured to control a temperature of a circuit component 1326 of the wafer, a conductive control terminal 1329 along the side 1312, and a conductive reference terminal 1325 that laterally surrounds the conductive control terminal 1329 along the side 1312 of the wafer, as well as separating a semiconductor die 1310 with the thermoelectric cooler TEC from the wafer, attaching the semiconductor die 1310 to a substrate or lead frame, and forming a package structure 1308 that encloses a portion of the semiconductor die 1310. In one implementation, forming the thermoelectric cooler TEC includes forming the conductive reference terminal 1325 as a first conductive bump along the side 1312 and forming the conductive control terminal 1329 as a second conductive bump along the side 1312. In these or another example, forming the thermoelectric cooler TEC includes forming the thermal channel 1307 as a conductive lattice structure 1307 along the side 1312, where the conductive lattice structure 1307 laterally surrounds the conductive control terminal 1329 along the side 1312, and the conductive reference terminal 1325 laterally surrounds the conductive lattice structure 1307 along the side 1312.

Modifications are possible in the described examples, and other implementations are possible, within the scope of the claims.

What is claimed is:

1. An electronic device, comprising:
a semiconductor die having opposite first and second sides, a semiconductor layer extending to the first side, a metallization structure extending from the semiconductor layer to the second side, an array of unit cells arranged in rows along a first direction and columns along an orthogonal second direction, and a conductive reference terminal in the semiconductor layer that laterally surrounds the array of unit cells, the first and second sides being spaced apart from one another by a thickness distance along a third direction that is orthogonal to the first and second directions, the thickness distance being 30 μm or more and 50 μm or less, and the respective unit cells including:
a circuit component in the semiconductor layer;
a holey semiconductor portion in the semiconductor layer that laterally surrounds the respective circuit component and includes holes that extend from the metallization structure toward the first side; and
a conductive control terminal in the semiconductor layer that laterally surrounds the respective holey semiconductor portion; and
an adhesive layer between the first side of the semiconductor die and a die attach pad.

2. The electronic device of claim 1, wherein:
the holey semiconductor portion and the conductive control terminal form a thermoelectric cooler of the respective unit cells; and
the semiconductor die includes a control circuit configured to provide a control voltage signal to the conductive control terminal to control a temperature of the circuit component of a respective one of unit cells.

3. The electronic device of claim 2, wherein the adhesive layer provides a thermal load to the thermoelectric cooler of the respective unit cells.

4. The electronic device of claim 3, wherein:
the holes of the holey semiconductor portion are spaced apart from the first side of the semiconductor die along the third direction by a non-zero spacing distance; and
the non-zero spacing distance is less than a thickness of the adhesive layer along the third direction.

5. The electronic device of claim 2, wherein the control circuit is configured to provide the control voltage signal to the conductive control terminal at a voltage relative to a voltage of the conductive reference terminal to control heating or cooling of the thermoelectric cooler of the respective unit cells.

6. The electronic device of claim 2, wherein:
the holes of the holey semiconductor portion are spaced apart from the first side of the semiconductor die along the third direction by a non-zero spacing distance; and
the non-zero spacing distance is less than a thickness of the adhesive layer along the third direction.

7. A method of fabricating an electronic device, the method comprising:
forming an array of unit cells in a semiconductor layer of a wafer, the unit cells arranged in rows along a first direction and columns along an orthogonal second direction, the respective unit cells including a circuit component in the semiconductor layer and a conductive control terminal laterally surrounding a lateral periphery of the respective unit cell in the semiconductor layer;
forming a conductive reference terminal laterally surrounding the array of unit cells in the semiconductor layer;
forming holes into a front side of the semiconductor layer in each unit cell along a third direction that is orthogonal to the first and second directions, the holes laterally surrounding the circuit component and laterally inward of the conductive reference terminal in each respective unit cell;
back grinding an opposite back side of the semiconductor layer such that the holes are spaced apart from the back side of the semiconductor die along the third direction by a non-zero spacing distance;
separating a semiconductor die with a portion of the semiconductor layer from the wafer; and
engaging the back side of the semiconductor die to an adhesive layer to attach the semiconductor die to a die attach pad.

8. The method of claim 7, further comprising:
forming a metallization structure on the front side of the semiconductor layer and covering the holes.

9. The method of claim 8, wherein back grinding the back side of the semiconductor layer sets a thickness of the wafer along the third direction to 30 μm or more and 50 μm or less.

10. The method of claim 7, wherein back grinding the back side of the semiconductor layer sets a thickness of the wafer along the third direction to 30 μm or more and 50 μm or less.

11. An electronic device, comprising:
a semiconductor die having opposite first and second sides, a semiconductor layer extending to the first side, a circuit component in the semiconductor layer, a metallization structure extending from the semiconductor layer to the second side, and a thermoelectric cooler, the thermoelectric cooler including a thermal channel configured to control a temperature of the circuit component, a conductive control terminal along the second side, and a conductive reference terminal that laterally surrounds the conductive control terminal along the second side;
a conductive lead coupled to the circuit component of the semiconductor die; and
a package structure that encloses a portion of the semiconductor die.

12. The electronic device of claim 11, wherein:
the conductive reference terminal is a first conductive bump along the second side; and
the conductive control terminal is a second conductive bump along the second side.

13. The electronic device of claim 12, wherein:
the thermal channel includes an array of further conductive bumps spaced apart from one another along the second side and arranged in rows along a first direction and columns along an orthogonal second direction;
the array of further conductive bumps laterally surrounds the conductive control terminal along the second side; and
the conductive reference terminal laterally surrounds the array of further conductive bumps along the second side.

14. The electronic device of claim 12, wherein:
the thermal channel includes a conductive lattice structure along the second side;
the conductive lattice structure laterally surrounds the conductive control terminal along the second side; and
the conductive reference terminal laterally surrounds the conductive lattice structure along the second side.

15. The electronic device of claim 11, wherein:
the thermal channel includes an array of conductive bumps spaced apart from one another along the second side and arranged in rows along a first direction and columns along an orthogonal second direction;
the array of conductive bumps laterally surrounds the conductive control terminal along the second side; and
the conductive reference terminal laterally surrounds the array of conductive bumps along the second side.

16. The electronic device of claim 11, wherein:
the thermal channel includes a conductive lattice structure along the second side;
the conductive lattice structure laterally surrounds the conductive control terminal along the second side; and
the conductive reference terminal laterally surrounds the conductive lattice structure along the second side.

17. A method of fabricating an electronic device, the method comprising:
forming a thermoelectric cooler along a side of a wafer, the thermoelectric cooler including a thermal channel configured to control a temperature of a circuit component of the wafer, a conductive control terminal along the side, and a conductive reference terminal that laterally surrounds the conductive control terminal along the side;
separating a semiconductor die with the thermoelectric cooler from the wafer;
attaching the semiconductor die to a substrate or lead frame; and
forming a package structure that encloses a portion of the semiconductor die.

18. The method of claim 17, wherein forming the thermoelectric cooler includes:
forming the conductive reference terminal as a first conductive bump along the side; and
forming the conductive control terminal as a second conductive bump along the side.

19. The method of claim 17, wherein:
forming the thermoelectric cooler includes forming the thermal channel as an array of conductive bumps spaced apart from one another along the side and arranged in rows along a first direction and columns along an orthogonal second direction;
the array of conductive bumps laterally surrounds the conductive control terminal along the side; and
the conductive reference terminal laterally surrounds the array of conductive bumps along the side.

20. The method of claim 17, wherein:
forming the thermoelectric cooler includes forming the thermal channel as a conductive lattice structure along the side;
the conductive lattice structure laterally surrounds the conductive control terminal along the side; and
the conductive reference terminal laterally surrounds the conductive lattice structure along the side.
